(19) United States
(12) Patent Application Publication
(10) Pub. No.: US 2004/0158641 A1
(43) Pub. Date: Aug. 12, 2004

(54) Method and apparatus for conveying network data and quasi-static data using a single data stream filter

(76) Inventors: Christopher Poli, Doylestown, PA (US); Jeff Gruber, Doylestown, PA (US)

Correspondence Address: Jack I. J'Maev, 11800 CENTRAL AVE., SUITE 110, CHINO, CA, 91710, US

(21) Appl. No.: 10/361,711

(22) Filed: Feb. 7, 2003

(51) Int. Cl. G06F 15/16; H04L 12/26; G01R 31/08; H04J 3/14; H04J 1/16

(52) U.S. Cl. 709/231; 370/230.1

(57) ABSTRACT

A single data stream filter dwells on a network data stream. A version identifier reflecting the status of quasi-static data carried on a different data stream is encapsulated in a network message. The network message is propagated by the network data stream according to a network protocol. The version identifier is extracted from the network message and compared against a previously stored version identifier. Based on the comparison, the data stream filter is tuned to receive the quasi-static data when an updated version of the data is needed.

### FIELD OF THE INVENTION

The present invention pertains to the field of cable television reception; specifically to the receipt of digital information from a cable television system.

### BACKGROUND OF THE INVENTION

In most cable television systems, subscribers are typically provided with a special communications terminal called a set top box. The set top box contains electronic equipment that enables a standard television receiver to receive programming from a cable television system. Traditionally, the set top box translated the carrier frequencies of television channels carried by the cable system into carrier frequencies that could be received by conventional television sets. Today, the set top box is a sophisticated computing platform that is capable of receiving digital television signals from a broad-band distribution network.

Cable television service has evolved far beyond basic television. Today, cable television systems offer subscribers premium movie channels, pay-per-view events and a plethora of other audio and video content. In order to support these expanded services, cable television systems have needed to increase the amount of programming content that the “cable” can carry. One solution for increasing the programming capacity of a cable television system is to “go digital”. By going digital, many cable systems have enjoyed a better-than five-fold increase in their program carrying capacity. Once a cable system converts to digital signaling, it is also able to offer other services such as access to wide area networks, for example the Internet.

Many cable television system rely on digital packet communications technology defined by the Motion Picture Experts Group (MPEG) and standardized in the broadband cable television service industry. This packet-based technology standardizes the sampling and digitization of, for example, the video and audio signals that constitute common television programming. The MPEG standard also defines a transport mechanism for conveying digital programming. This transport mechanism defines a rudimentary packet that can be used to carry digital data. Each packet comprises a header. The header contains information pertaining to the data in the packet. Each packet further comprises a packet payload that can be used to carry video, audio samples or other arbitrary digital data.

Streams of these rudimentary packets are called packetized elementary streams (PES). Several of these packet streams, according to the MPEG standard, are aggregated to form a transport stream packet (TSP). Each PES carried by a cable television system is generally used to carry a particular program. As a result of this application, packet elementary streams have come to be associated with a program identifier PID and the term “PID stream” is often used to refer to a stream of elementary packets associated with a particular program. PID streams are generally numbered for identification and apportionment. For example, PID stream number 133 may be used to carry cable television channel 56.

A cable television system typically comprises a “head-end”. The head-end typically provides the equipment necessary to deliver programming content to subscribers. For example, a head-end typically includes a receiver that is capable of receiving a television signal. Once the television signal is digitized, the individual digital samples constituting the signal are committed to a particular PID stream. The PID stream is then aggregated with other PID streams to form a transport stream. This transport stream is then conveyed to the cable television system distribution network.

On the receiving end, i.e. in a set top box, a PID number is used to extract packets from the TSP stream in order to reconstitute a packet elementary stream, i.e. a “PID stream”. Following the previous example, the set top box would receive packets from PID stream number 133 when a user selects channel 56. To accomplish this, the set top box scans the incoming TSP data stream and retains only those packets that are associated with the PID corresponding to the selected channel. Once those packets are acquired, they are processed prior to presentation of a program to the user through, in most cases, a television set.

In a cable television system, different PID streams are used to carry various types of data. For instance, one PID stream may be used to carry a television program as already described. Other PID streams may be used to convey various housekeeping information from the head-end to the set top box. This type of housekeeping information may be used by the cable television system to keep the set top box informed of the types of channels or other services that may be carried by different PID streams in a digital cable television system. In accordance with the MPEG standard, a system known as the Program Specific Information (PSI) System is used to generate much of this housekeeping information. The PSI system conveys data to set top boxes using various tables such as a Program Map Table (PMT), a Program Association Table (PAT), a Conditional Access Table (CAT), and a Network Information Table (NIT). Each of these tables is generally conveyed from the head-end using a particular numbered PID stream.

The PMT table disseminated by the PSI system is used to indicate what PID streams are being used to carry a particular television program channel. The CAT table is used by the set top box to determine if a particular subscriber has privileged access, e.g. has paid a subscription fee for a premium movie channel. Other tables are used to carry other information. The information disseminated by the PSI system is relatively static in that it rarely changes. Even still, the PSI system repetitively broadcasts these tables to all devices attached to the cable television's distribution network. One interesting aspect of the known art is that the head-end uses a different and distinct PID stream to convey each of these tables to the set top boxes attached to the distribution network.

The head-end also needs to communicate with each set top box attached to the cable television system. This is normally accomplished using computer network protocols. Data packets used to support these computer network protocols are transmitted downstream from the head end to each set top box using a particular PID stream. This PID stream is often called the “network data” PID stream.

In order to manage such an onslaught of information and to correctly associate each incoming packet with its proper PID stream, set top boxes typically contain special purpose hardware, generically called PID filters (or data stream filters), that can be programmed to receive specific PIDs. Given the high speed (and hence high cost) of the hardware required to do the PID detection, the number of PIDs that can be simultaneously detected by a set top box may be limited.

Because cable television housekeeping information is so important, it is common for a set top box to dedicate data stream filters to receiving it. It is important to note that the housekeeping information is carried by several different PID streams, and a separate PID filter must be allocated to each form of housekeeping data in order to ensure proper reception. At the same time, because computer network communications between the head-end and the set top boxes also must be supported, set top boxes also dedicate yet another PID filter to the task of receiving the network data PID stream.

Designers of set top boxes have had some choices as to how to use the preceding information in their designs. At one extreme, a separate data stream filter is dedicated to each of the separate PID streams including network data and the PAT, CAT, PMT, and NIT tables. This approach requires five dedicated data stream filters for receiving packets that change very infrequently.

Some implementers have chosen to dedicate only a single PID filter to the reception of network, PAT, CAT, PMT, and NIT packets and to employ a round-robin mechanism for updating received information. According to this approach, a set top box tunes to the network PID and receives network information. The data stream filter is then tuned to the PAT PID so that updated PAT information can be received. This round-robin scheme continues through a cycle so that the CAT, PMT, and NIT tables can be updated. After the NIT information is updated the data stream filter again is tuned to the network PID, and the process is repeated. Note that this process is not intelligent. If information in the various tables has not changed, it is updated anyway on a periodic basis consistent with the round-robin method.

In some set top boxes, the network data PID is included in the round-robin tuning of a single PID filter, but this has proven to be undesirable because computer network data can be lost during periods when the single data stream filter is not tuned to the network data PID. Hence, the most set top boxes are designed so as to provide a separate PID filter dedicated to the reception of network data.

An important additional component of the TSPs processed in today's set top box includes Program and System Information Protocol (PSIP) packets. These are used by the cable television service to transmit schedule information. PSIP packets normally employ a PID of 0×1FFB (Hexadecimal) and contain several tables, including a System Time Table (STT) that provides date and time of day information, a Master Guide Table (MGT) containing version information, size, and PIDs of other tables in the PSIP system, a Virtual Channel Table (VCT) that describes all virtual channels in a given transport stream, and a Rating Region Table (RRT) containing geographically-related program rating information. Other tables included in the PSIP system are beyond the scope of this brief introduction.

Accordingly, the feature of PSIP whereby version information for all tables in the PSIP system is included in the MGT provides the set top box designer with an efficient way to handle PSIP data using a single data stream filter: Tune the filter to the 0×1FFB value and monitor the version information in the MGT. When the version of one of the PSIP tables changes, reprogram the data stream filter to accumulate and process the new data. Thereafter, reset the data stream filter tuning to 0×1FFB and await further changes in the versions of the PSIP tables.

The techniques already described typically dedicate one data stream filter to the round-robin reception of CAT, PAT, PMT, and NIT PID streams. A second data stream filter is normally allocated to the task of receiving the computer network data PID stream and a third data stream filter is normally dedicated to the reception of PSIP packets, which is also conducted in a modified round-robin manner. Given that all of these data streams, with the exception of the network data PID, change quite slowly, it is wasteful to incur the expense of the extra data stream filters that need to be dedicated to the reception of cable television system housekeeping information.

### SUMMARY OF THE INVENTION

What is needed, then, is some means for reducing the number of data stream filters that are needed to receive set top box housekeeping information and network data packets. The present invention comprises a method for receiving quasi-static data. The present invention further comprises a method for transmitting quasi-static data that is compatible with the reception technique that constitutes the invention. The present invention further comprises an apparatus that is capable of receiving both network data packets and quasi-static data using a single data stream filter.

According to one illustrative variation of the present method, a version identifier corresponding to quasi-static data is received from a first data stream. When the version identifier indicates that the quasi-static data has been updated, the method of the present invention provides that quasi-static data is received from a second data stream. Both the first and second data streams are received using a single data stream filter. Generally, the present inventive method provides that the data stream filter dwells on the first data stream from whence a version identifier for some quasi-static data is received.

In yet another alternative method, the receipt of a quasi-static data version identifier is accomplished by extracting a network data stream from a transport stream. The extraction of the network data stream is effected by the use of a program identifier. According to yet another variation of the present method, a transport stream is received by receiving a modulated carrier signal. A bit stream is recovered from the modulated single and framed into transport packets. Transport packets are selected from the transport stream according to the program identifier yielding a network data stream.

In one illustrative method of the present invention, transport packets constituting a network data stream are repackaged into data packets that are compatible with a network protocol. The network protocol data packets are then assembled into network messages containing a version identifier.

According to yet another variation of the present method, quasi-static data is received by extracting a quasi-static data stream from the transport stream. This is accomplished by causing the data stream filter to select a data stream according to a quasi-static data program identifier. Once the quasi-static data has been received, the data stream filter is again directed to receive a data stream according to the program identifier corresponding to a network data stream. It should be noted, that the scope of the present invention is not intended to be limited to the reception of any particular type of quasi-static data. In one illustrative method that is not intended to limit the scope of this invention, a data stream is extracted from the transport stream by using a program identifier that corresponds to at least one of a program map table, a program association table, a conditional access table, a network information table and program and system information protocol data.

Quasi-static data is transmitted according to the present invention by monitoring the version status of the quasi-static data. A version message reflecting the current version status of a particular quasi-static data is generated and conveyed to a network data stream. Generally, the version message is fragmented into one or more data packets in accordance with a network protocol. According to one variation of the present method, the network protocol data packets are repackaged into data packets compatible with the transport stream. Then, a carrier signal is a modulated according to the transport stream data packets. The modulated carrier signal is then directed to a transmission medium.

In yet another alternative method of the present invention, the data packets constituting a network data stream are associated with a particular program identifier. Quasi-static data, according to yet a different variation of the present method, is associated with a different and particular program identifier. It should be noted that quasi-static data according to one variation of the present method that is not intended to limit the scope of this invention is transmitted using a program identifier that corresponds to at least one a program map table, a program association table, a conditional access table, a network information table and program system information protocol data.

A receiver according to the present invention comprises a stream receiver and a quasi-static data versioning unit. Commensurate with the teachings of the present method, the stream receiver is capable of receiving either a network data stream or a quasi-static data stream. The quasi-static data versioning unit is capable of receiving a quasi-static data version identifier from the network data stream. The quasi-static data versioning unit directs the stream receiver to receive quasi-static data when the version identifier indicates that the quasi-static data has been updated.

According to one example alternative embodiment of the present invention, the stream receiver comprises a network data program identifier determination unit and a stream reception front-end. The network data program identifier determination unit generates a network data selector signal that is used to direct the stream reception front-end to receive a network data stream.

According to yet another alternative embodiment of the present invention, the stream receiver front-end comprises a signal receiver, a demodulator, a transport framer and a data stream filter. The signal receiver is capable of receiving a modulated signal whereas the demodulator recovers a bit stream from the modulated signal. This bit stream is then framed into transport data packets by the transport framer. As transport data packets are framed, specific packets are selected by the data stream filter according to a program identifier. According to yet another alternative embodiment of the present invention, the stream reception front-end further comprises a program identification selection unit. This selection unit selects either the network data selector generated by the network data program identifier determination unit or a quasi-static-data selector.

In yet another alternative illustrative embodiment of the present intention, the data versioning unit in a quasi-static data receiver comprises a network data receiver and a version comparison unit. The network data receiver extracts a quasi-static data version identifier from the network data stream. The version comparison unit generates a quasi-static data program identifier when the extracted version identifier is newer than a previously stored version identifier. According to another illustrative embodiment of the invention, the network data receiver comprises a network framer and a network message assembler. The network data framer is typically used to repackaged a data packet from the network data stream into a data packet that is compatible with a network protocol. The network message assembler is then able to assemble the network compatible data packets into network messages according to a network protocol. In yet another alternative example embodiment of the invention, the version comparison unit generates a quasi-static data program identifier corresponding to at least one of a program map table, a program association table, a conditional access table, a network information table and program and system information protocol data.

The present invention further comprises a quasi-static data transmitter. According to one illustrative embodiment, the quasi-static data transmitter comprises a quasi-static data monitor that generates a version identifier whenever quasi-static data has changed. The quasi-static data transmitter further comprises a message encapsulator. The message encapsulator packages the version identifier into a network message. In order to propagate the network message, the quasi-static data transmitter further comprises a transport stream generator that receives the network message and includes the message in a transport stream. According to one example embodiment of a quasi-static data transmitter, the data monitor generates a version identifier corresponding to at least one of a program map table, a program association table, a conditional access table, a network information table and program and system information protocol data.

One illustrative embodiment of a transport stream generator comprises a packetizer, a multiplexer, a serializer and a modulator. The quasi-static data transmitter of this illustrative embodiment propagates a network message by directing the message to packetizer. The packetizer fragments the network message into one or more data packets. Typically, these data packets are associated with a particular program identifier, i.e. a network PID. The multiplexer interleaves the data packets associated with the network PID with other data packets and delivers the multiplex stream of data packets to the serializer. The serializer converts the data packets into a serial bit stream. The modulator then generates a modulated signal according to this serial bit stream.

### BRIEF DESCRIPTION OF THE DRAWINGS

The present invention will hereinafter be described in conjunction with the appended drawings and figures, wherein like numerals denote like elements, and in which:

FIG. 1 is a flow diagram depicting one illustrative method of receiving network data and quasi-static data using a signal data stream filter according to the present invention;

FIG. 2 is a flow diagram illustrating one example method of extracting a network data stream from a transport stream according to the present invention;

FIG. 3 is a flow diagram that illustrates one possible method of extracting a version identifier message from an extracted network data stream according to the present invention;

FIG. 4 is a flow diagram that describes one example technique of extracting a quasi-static data stream from a transport stream according to the method of the present invention;

FIG. 5 is a flow diagram depicting one example method of transmitting quasi-static data on a data stream and of associating the transmitted quasi-static data with a network version identifier message according to the present invention;

FIG. 6 is a block diagram illustrating one possible example embodiment of a network data and quasi-static data receiving device that may implement the method of the present invention; and

FIG. 7 is a block diagram that depicts one illustrative embodiment of a device that transmits network data and quasi-static data according to the method of the present invention.

### DETAILED DESCRIPTION OF THE INVENTION

According to one variation of the method of the present invention, both network data and so-called quasi-static data are received using a single data stream filter. Quasi-static data refers to data that typically changes only slowly with time. Quasi-static data is abbreviated as “Q-S” data in the figures. The terminology “data stream filter” is used in the present description to mean a combination of hardware and software elements in a receiving device that together cause packets from a desired data stream to be selected from a received transport data stream. A data stream filter comprises, for example, a programmable hardware element called a packet identifier (PID) filter that identifies packets to be selected. A data stream filter, according to one alternative embodiment of the invention, further comprises other hardware and software elements that accomplish the actual selection of packets from the data stream. The resulting sequence of selected packets is typically called a “PID stream”.

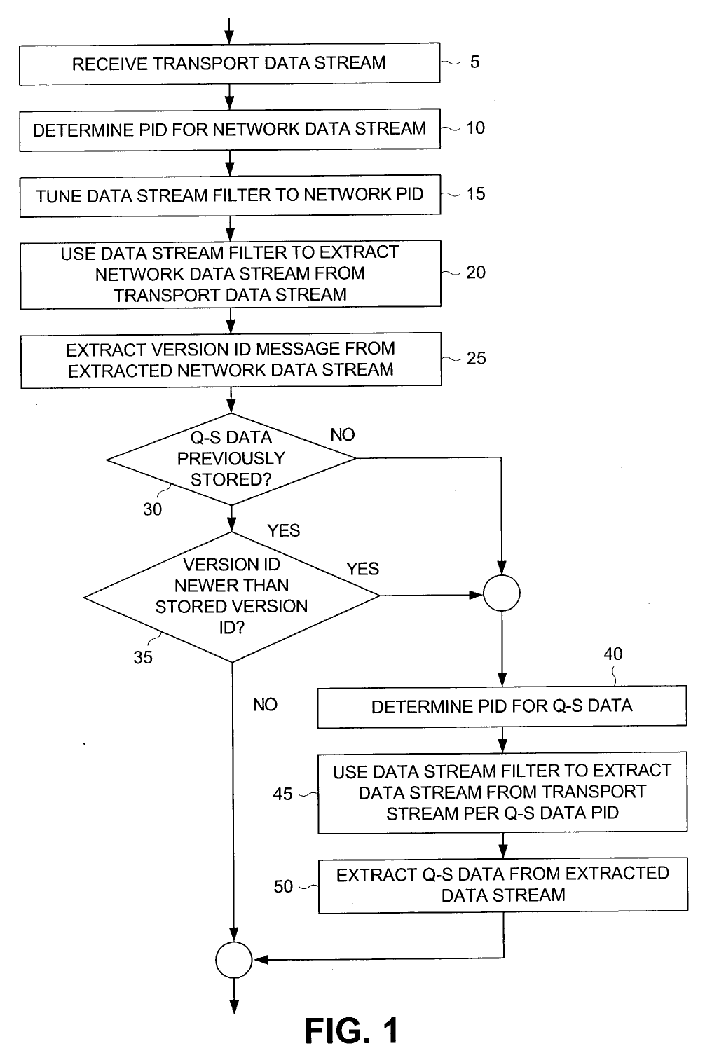

FIG. 1 is a flow diagram depicting one illustrative method of receiving network data and quasi-static data using a single data stream filter according to the present invention. According to this illustrative method, a transport stream carrying a plurality of PID streams is received (step 5). This plurality of PID streams typically includes a network data stream that is associated with a unique PID. The PID for the network data PID stream is first determined (step 10), and a data stream filter is tuned to the network PID (step 15). The data stream filter extracts the network data stream from the transport data stream (step 20). With the network data stream now extracted, a version identifier message associated with quasi-static data further is extracted from the extracted network data stream (step 25). In one example variation of the present method, this is accomplished by collecting data packets from the network data stream and directing those packets to a network protocol manager. The network protocol manager assembles the packets into messages, wherein a particular message is a quasi-static data version message that comprises a version identifier.

One variation of the present method determines whether quasi-static data and an associated version identifier previously have been received and stored (step 30). When quasi-static data and an associated version identifier previously have been stored, the version identifier in the just-received version identifier message is compared with the stored version identifier (step 35). When the just-received version identifier is not newer than the stored version identifier, the entire process simply is repeated starting at step 5. When the just-received version identifier is newer than the stored version identifier (step 35) or when quasi-static data and an associated version identifier previously have not been stored (step 30), then the PTD for the quasi-static data is determined (step 40). The data stream filter is then tuned to the PID of the quasi-static data, and the data stream filter extracts the quasi-static data stream from the transport stream (step 45). Then the quasi-static data, itself, is extracted from the quasi-static data stream (step 50).

According to one variant of the present invention, quasi-static data is received in the form of one or more of a Program Association Table (PAT), a Conditional Access Table (CAT), a Program Map Table (PMT), and a Network Information Table (NIT). In yet another variant of the present method, quasi-static data is received in the form of Program and System Information Protocol (PSIP) packets. Quasi-static data, according to another alternative method, is received in the form of other slowly-varying data that is associated with a particular PID. It should be understood that these examples are for illustration only and should not be construed to limit the intended scope of the present invention.

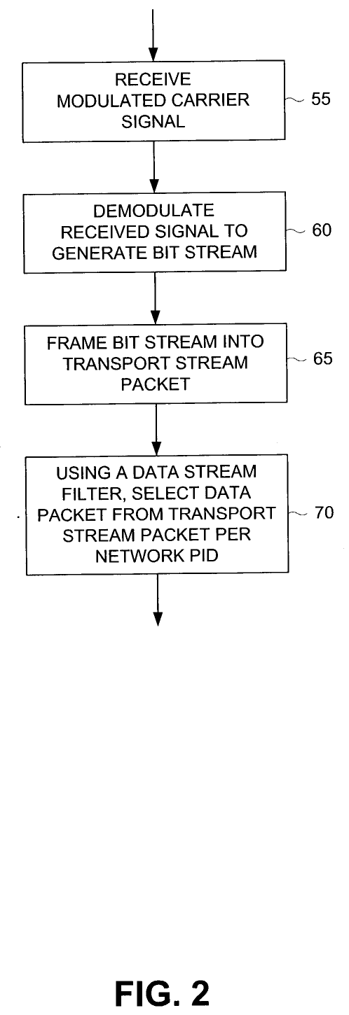

FIG. 2 is a flow diagram illustrating one example method of extracting a network data stream from a transport stream according to the present invention. According to this example variation of the present method, a transport stream is received, for example by way of a modulated radio frequency carrier signal (step 55). The received signal is demodulated to produce a received bit stream (step 60) that is framed into a sequence of transport stream packets (step 65). A data stream filter selects network data packets from the transport stream according to the network PID identifier (step 70). The resulting sequence of data packets comprises a network data packet stream. It should be noted that when a modulated signal is used to carry a transport stream, it may be modulated in amplitude and phase using a technique called quadrature amplitude modulation, or “QAM”. This modulation technique is commonly used in the cable television industry, but the invention is not intended to be limited to any one form of modulation that may be used to encode the transport stream.

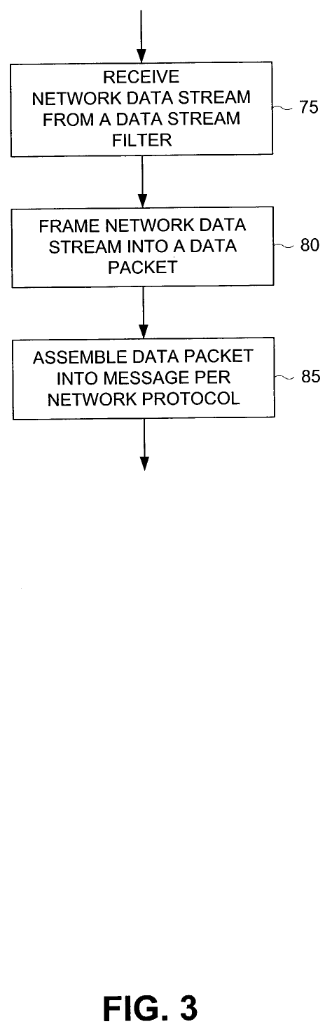

FIG. 3 is a flow diagram that illustrates one possible method of extracting a version identifier message from an extracted network data stream according to the present invention. According to this illustrative method, a network data stream is received (step 75). As the received network data stream may take the form of a bit stream, the network data stream may be framed into a sequence of data packets (step 80). The data packets are assembled into a version identifier message according to a network protocol (step 85). In one example method of the present invention, the bit stream may comprise a PMT version identifier.

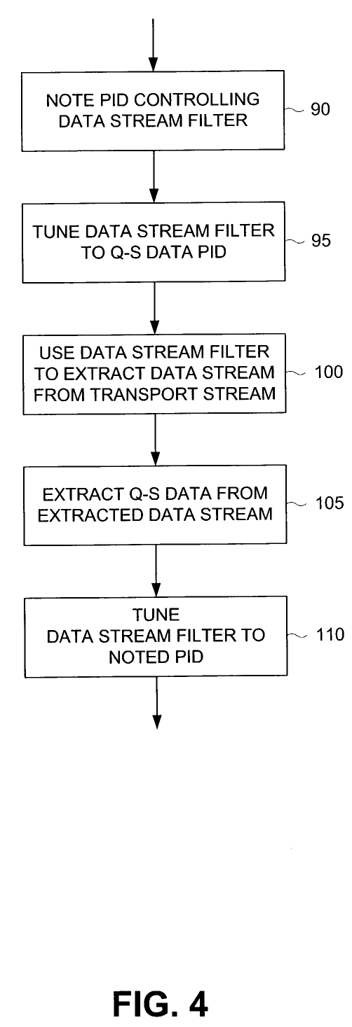

FIG. 4 is a flow diagram that illustrates one example technique of extracting a quasi-static data stream from a transport stream according to the method of the present invention. In this example, a data stream filter initially is programmed to receive a network data stream, and an updated version identifier message already may have been received and detected. Therefore, the PID (which may be the network PID) controlling the data stream filter is noted and temporarily stored (step 90). The data stream filter is then directed to receive data according to the PID identifier associated with the quasi-static data corresponding to the updated version identifier (step 95). The data stream filter then extracts the quasi-static data stream from the transport data stream according to the controlling PID (step 100). Quasi-static data then is extracted (step 105) from the quasi-static data stream received by the data stream filter and is stored, and the temporarily stored PID is retrieved and again used to control the data stream filter (step 110).

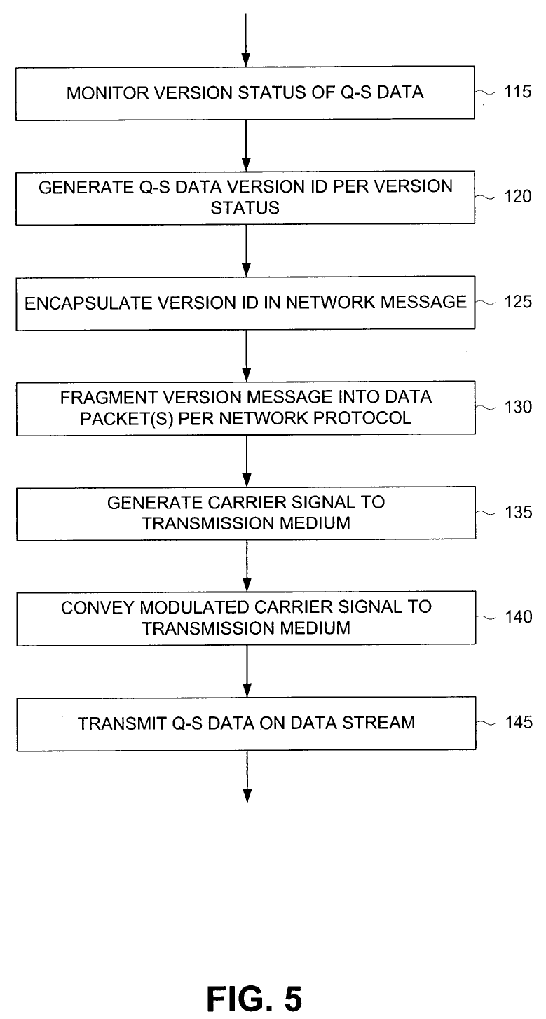

FIG. 5 is a flow diagram depicting one example method of transmitting quasi-static data on a data stream and of associating the transmitted quasi-static data with a network version identifier message according to the present invention. In this illustrative variation of the present method, the version status of quasi-static data is monitored (step 115), and an updated version identifier for the quasi-static data is generated according to the version status, i.e. when the version status indicates that a new version exists (step 120). This version identifier is typically encapsulated in a network message (125). The network message is fragmented into a sequence of data packets according to a network protocol (step 130). A carrier signal modulated according to the data packet sequence is generated (step 135) and conveyed to a transmission medium (step 140). Meanwhile, the updated quasi-static data may be transmitted on its associated data stream, i.e. PID stream (step 145).

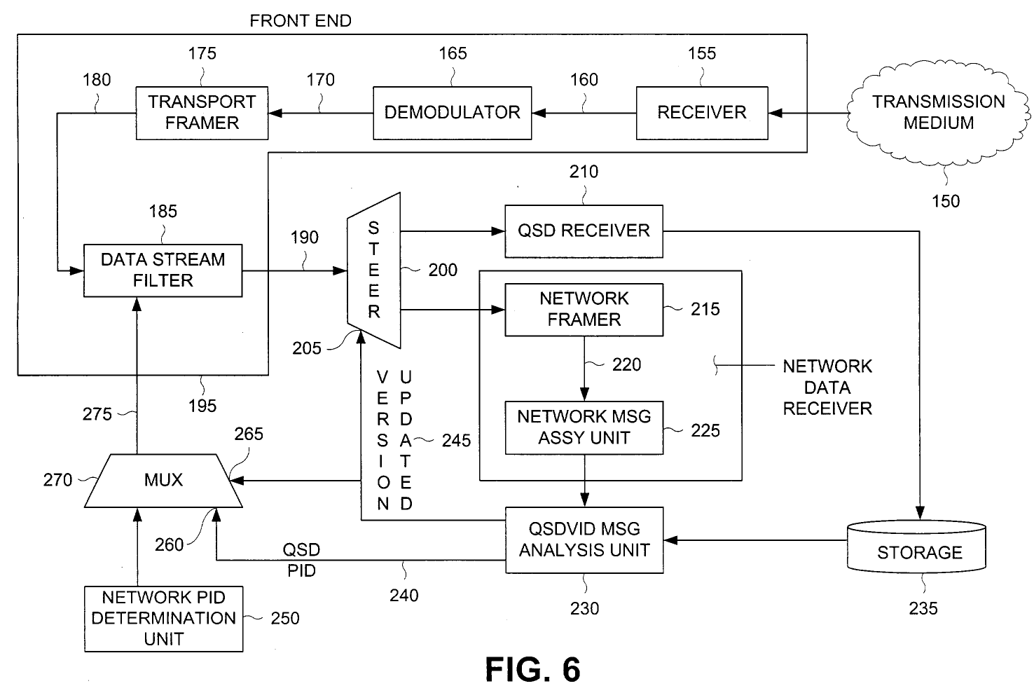

FIG. 6 is a block diagram illustrating one possible example embodiment of a network data and quasi-static data receiving device that implements the method of the present invention. According to this illustrative embodiment, a receiving device comprises a front-end 195 that comprises a receiver 155, a demodulator 165, a transport stream framer 175 and a data stream filter 185. Accordingly, the receiver 155 receives a signal 160 from a transmission medium 150, e.g. a cable television system broadband cable. However, the scope of the present invention is not intended to be limited to reception of a signal from any particular type of medium. For example, the receiver in one alternative embodiment of the invention receives a signal from the ether (i.e. a wirelessly conveyed signal).

The received signal 160 is demodulated by the demodulator 165 to produce a bit stream 170 that in one embodiment constitutes a transport data stream. The transport data stream is analyzed by the transport framer 175 to produce a sequence of packets 180. These packets are packetized elementary stream (PES) packets that collectively form a transport stream. Each of these PES packets is associated with a particular packet identifier (PID). The TSP sequence 180 is applied to the input of the data stream filter 185 that acts to select packets from the TSP according to their PID. The data stream filter 185 selects packets according to a PID selection parameter 275 that forms a control input to the data stream filter 185.

In one illustrative embodiment of the present invention, the receiving device further comprises a network PID determination unit 250, a multiplexer 270, a steering unit 200, a QSD receiver 210, a network framer 215, a network message assembly unit 225, a QSD version identification message analysis unit 230, and a storage unit 235. In one illustrative mode of operation, the selection parameter 275 input to the data stream filter 185 is selected by the multiplexer 270 from the network PID determination unit 250 so that the data stream filter 185 receives a network data PID stream. Accordingly, a version updated signal 245 is not asserted, so the steering unit 200 directs data packets constituting a PID stream 190 from the data stream filter 185 to the network framer 215. The network framer 215 frames the PID stream packets 190 into packets that subsequently are assembled into a network message by the network message assembly unit 225. In yet another example embodiment of the invention, the network framer 215 receives MPEG packets that are 188 bytes long and repackages the data contained therein into data packets compatible with the input of the network message assembly unit 225, for example into 256 byte packets.

Network messages are passed from the network message assembly unit 225 to the QSD version identifier (QSDVID) message analysis unit 230 that extracts a QSDVID message from the network message. The QSDVID message analysis unit 230 then accesses a stored QSDVID stored in the storage unit 235 and compares the received QSDVID with the stored QSDVID. If the received QSDVID differs from the stored QSDVID or if a previous QSDVID has not been stored, then the QSDVID message analysis unit 230 determines the PID of the received QSDVID, which according to one example embodiment of the invention is extracted from the network message containing the QSDVID, and passes the received QSDPID (as QSDPID 240) to the multiplexer 270. The QSD version identifier (QSDVID) message analysis unit 230 also asserts the version updated signal 245. Asserting the version updated signal 245 causes the multiplexer 270 to present the QSDPID 240 as the selection parameter 195 for the data stream filter 185 whence the output 190 of the data stream filter 185 becomes the PID stream associated with the QSD. Asserting the version updated signal 245 also causes the steering unit 200 to direct the output 190 of the data stream filter 185 to the QSD receiver 210. The QSD receiver 210 extracts QSD information from the packets constituting the PID stream it receives from the data stream filter 185 and stores the QSD information into the storage unit 235.

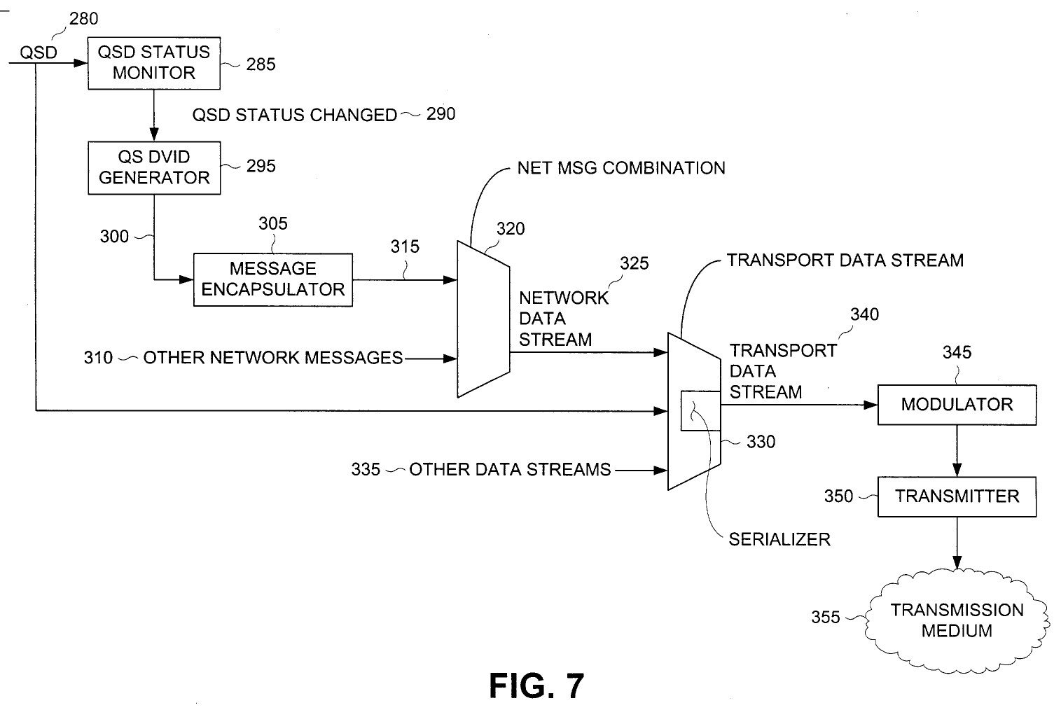

FIG. 7 is a block diagram that depicts one illustrative embodiment of a device that transmits network data and quasi-static data according to the method of the present invention. This illustrative embodiment comprises a quasi-static data status monitor 285, a quasi-static data version identifier generator 295, a message encapsulator 305, a network message combiner 320, a transport combiner 330, a modulator 345, and a transmitter 350. In this illustrative embodiment quasi-static data (QSD) 280 is monitored by the QSD status monitor 285. The QSD status monitor 285 determines whether QSD has changed. When the status of QSD changes, the QSD status monitor 285 generates a QSD status changed signal 290. Upon receiving a QSD status changed signal 290, the QSDVID generator generates a new version identifier, for example by incrementing a version counter. The QSDVID 300 is encapsulated into a network message 315 by the message encapsulator 305. The encapsulated message 315 is presented to the input of the network message combiner 320. The network message combiner 320 multiplexes the encapsulated QSDVID message 315 with other network messages 310 according to a network protocol to produce a network data stream 325. This network data stream is a PID stream that is identified by a particular PID number.

The QSD 280 still further is presented to the input of the transport combiner 330 as a PID stream identified by a PID number different that the PID number of the network data PID stream. The transport combiner 330 interleaves the network data PID stream 325 and the QSD PID stream 280 together with other data streams 335 according to a transport protocol (e.g. MPEG) to generate a transport data stream 340. The transport combiner, according to one alternative embodiment of the invention, further comprises a serializer that converts interleaved packets into a serial bit stream. The modulator 345 generates a signal that is modulated according to the transport data stream 340, noting that in one embodiment the transport data stream 340 is a serial bit stream. This signal is then conveyed to a transmission medium 355 by the transmitter 350. Again, it should be noted that the transmission medium may in fact be the ether when a wireless conveyance is desired.

Alternative Embodiments

While this invention has been described in terms of several preferred embodiments, it is contemplated that alternatives, modifications, permutations, and equivalents thereof will become apparent to those skilled in the art upon a reading of the specification and study of the drawings. It is therefore intended that the true spirit and scope of the present invention include all such alternatives, modifications, permutations, and equivalents.

What is claimed is:

1. A method for receiving quasi-static data using a single data stream filter comprising:
receiving a quasi-static data version identifier from a first data stream; and
receiving quasi-static data from a second data stream when the received version identifier indicates that quasi-static data has been updated.

2. The method of claim 1 wherein receiving a quasi-static data version identifier comprises:
extracting a network data stream from a transport stream according to a network data stream program identifier using the data stream filter; and
extracting a version identifier message from the extracted network data stream.

3. The method of claim 2 wherein extracting a network data stream comprises:
receiving a modulated carrier signal;
recovering a bit stream from the modulated carrier signal;
framing the bit stream into a stream of transport packets; and
selecting a data packet from the stream of transport packets according to a network program identifier using the data stream filter.

4. The method of claim 2 wherein extracting a version identifier message comprises:
receiving a network data stream packet from the data stream filter;
framing the network data stream packet into a network protocol data packet; and
assembling the network protocol data packet into a message according to a network protocol.

5. The method of claim 1 wherein receiving quasi-static data comprises:
extracting a quasi-static data stream from a transport stream according to a quasi-static data program identifier using the data stream filter; and
extracting the quasi-static data from the extracted data stream.

6. The method of claim 5 wherein extracting a quasi-static data stream comprises:
noting the program identifier controlling the data stream filter;
causing the data stream filter to select a data stream according to a quasi-static data program identifier;
extracting a data stream from a transport stream using the data stream filter;
extracting quasi-static data from the extracted data stream; and
causing the data stream filter to select a data stream according to the noted program identifier.

7. The method of claim 1 wherein receiving quasi-static data from a second data stream comprises the steps of:
extracting a data stream from a transport stream according to a program identifier corresponding to at least one of a program map table data and a program association table data and a conditional access table data and a network information table data and program and system information protocol data using the data stream filter; and
extracting the quasi-static data from the extracted data stream.

8. A method for transmitting quasi-static data comprising the steps of:
monitoring the version status of quasi-static data;
generating a version message according to said version status;
conveying the version message to a network data stream; and
transmitting the quasi-static data on a quasi-static-data data stream.

9. The method of claim 8 wherein generating a version message comprises:
generating according to said version status, a version identifier for quasi-static data consisting of at least one of a program map table data and a program association table data and a conditional access table data and a network information table data and program and system information protocol data; and
encapsulating the version identifier in a network message.

10. The method of claim 8 wherein conveying the version message to a network data stream comprises:
fragmenting the version message into one or more data packets in accordance with a network protocol;
generating a modulated carrier signal according to the data packets; and
conveying the modulated carrier signal to a transmission medium.

11. A quasi-static data receiver comprising:
a stream receiver for receiving either a network data stream or a quasi-static data stream; and
a quasi-static data versioning unit that:
receives a quasi-static data version identifier from the network data stream; and
directs the stream receiver to receive the quasi-static data stream when the quasi-static data version identifier indicates that the quasi-static data has been updated.

12. The quasi-static data receiver of claim 11 wherein the stream receiver comprises:
a network data program identifier determination unit that generates a network data selector signal; and
a stream reception front-end that receives a network data stream according to the network data selector signal.

13. The quasi-static data receiver of claim 12 wherein the stream reception front-end comprises:
a signal receiver for receiving a modulated signal;
a demodulator that recovers a bit stream from the modulated signal;
a transport framer that frames the bit stream into packets; and
a data stream filter that selects packets according to a program identifier.

14. The quasi-static data receiver of claim 13 wherein the stream reception front-end further comprises a program identification selection unit that directs either the network data selector or a quasi-static-data selector to the data stream filter as the program identifier.

15. The quasi-static data receiver of claim 11 wherein the quasi-static data versioning unit comprises:
a network data receiver that extracts a quasi-static data version identifier from the network data stream; and
a version comparison unit that generates a quasi-static data program identifier when the extracted version identifier is newer than a previously stored version identifier.

16. The quasi-static data receiver of claim 15 wherein the network data receiver comprises:
A network framer that repackages a data packet from the network data stream into a network protocol packet; and
a network message assembler that assembles the network protocol packet into a message according to a network protocol.

17. The quasi-static data receiver of claim 15 wherein the version comparison unit generates a quasi-static data program identifier corresponding to at least one of a program map table data, a program association table, a conditional access table, a network information table, and program and system information protocol data.

18. A quasi-static data transmitter comprising:
a quasi-static data monitor that generates a version identifier when it detects that the quasi-static data has changed;
a message encapsulator that packages the version identifier in a network message; and
a transport stream generator that includes the network message in a transport stream.

19. The quasi-static data transmitter of claim 18 wherein the data monitor generates a version identifier corresponding to at least one of a program map table data and a program association table data and a conditional access table data and a network information table data and program and system information protocol data.

20. The quasi-static data transmitter of claim 18 wherein the transport stream generator comprises:
a packetizer that fragments the network message into one or more packets associated with a network data program identifier;
a multiplexer that time-multiplexes the network message packets with other packets;
serializer that converts the multiplexed packets into a serial bit stream; and
a modulator that generates a modulated signal according to the serial bit stream.
